(19) United States
(12) Patent Application Publication
(10) Pub. No.: US 2020/0176417 A1
(43) Pub. Date: Jun. 4, 2020

(54) STACKED EMBEDDED PASSIVE SUBSTRATE STRUCTURE

(71) Applicant: QUALCOMM Incorporated, San Diego, CA (US)

(72) Inventors: Brigham NAVAJA, San Diego, CA (US); Yue LI, San Diego, CA (US); Kuiwon KANG, San Diego, CA (US); Soumyadipta BASU, San Diego, CA (US); Joan Rey Villarba BUOT, Escondido, CA (US)

(21) Appl. No.: 16/209,723

(22) Filed: Dec. 4, 2018

(51) Int. Cl. H01L 25/065; H01L 23/538; H01L 23/64; H01L 23/00; H05K 1/18

(52) U.S. Cl. CPC H01L 25/0657; H01L 23/5389; H01L 23/642; H01L 24/16; H01L 24/48; H01L 2924/1205; H01L 2924/14; H01L 2225/06541; H01L 2924/30105; H01L 2924/19041; H01L 2924/15311; H05K 1/186

(57) ABSTRACT

The present disclosure generally relates to an integrated circuit having a stacked embedded passive substrate (EPS) structure formed therein. In particular, a substrate may have a cavity formed therein and the stacked EPS structure may include multiple passive components formed in the cavity to provide separate electrical paths for decoupling of the integrated circuit. Furthermore, the multiple passive components may each have two respective terminals such that the multiple passive components may support different voltage domains. Among other things, compared to conventional die-side and/or land-side passive components, the stacked EPS structure may advantageously reduce a z-axis height of the integrated circuit, reduce manufacturing costs, improve performance due to shorter electrical paths, and improve design routing through x-axis and y-axis space savings.

### TECHNICAL FIELD

The present disclosure generally relates to integrated circuits, and more particularly, to stacked passive components embedded in a substrate structure.

### BACKGROUND

Passive components such as capacitors are often used in electronic packaging to reduce noise and impedance and to maintain a near-constant voltage under various operating frequencies. For example, an integrated circuit commonly includes or is coupled to a voltage regulator that converts available voltages to lower voltages used by the integrated circuit. The voltage regulator ensures a predictable power supply is provided to the integrated circuit, which is an important function because the ability of transistors to tolerate voltages under or over a target voltage is small. Mere tenths of a volt lower may create erratic results in the integrated circuits, while mere tenths of a volt higher may damage the integrated circuits.

As transistors in the integrated circuit turn on and off, the power load changes rapidly, thus placing additional demand on the voltage regulator. The distance between the voltage regulator and the integrated circuit creates a long response time due to inductance in the wire or trace between the transistor and the voltage regulator. This inductance prevents the voltage regulator from increasing power to the integrated circuit instantaneously, especially when the transistors switch on and off millions or billions of times each second. As the voltage regulators attempt to respond, ringing (or bouncing) may be occur. Passive components such as decoupling capacitors are therefore used to provide additional stability to the power supplied to the integrated circuits.

For example, decoupling capacitors attached in close proximity to the integrated circuit may provide a charge reservoir for the integrated circuit. As demand on the power supply changes rapidly, the capacitor provides additional power and can refill at a later time when power demand decreases. The decoupling capacitor allows the integrated circuit to operate at the high frequencies and computational speeds that consumers desire. The decoupling capacitor is typically a multi-layer ceramic capacitor (MLCC) that advantageously offers high reliability and low impedance characteristics. However, as transistor sizes have decreased and densities increased, finding area on the integrated circuit to place decoupling passive components becomes more difficult.

### SUMMARY

The following presents a simplified summary relating to one or more aspects and/or embodiments disclosed herein. As such, the following summary should not be considered an extensive overview relating to all contemplated aspects and/or embodiments, nor should the following summary be regarded to identify key or critical elements relating to all contemplated aspects and/or embodiments or to delineate the scope associated with any particular aspect and/or embodiment. Accordingly, the following summary has the sole purpose to present certain concepts relating to one or more aspects and/or embodiments relating to the mechanisms disclosed herein in a simplified form to precede the detailed description presented below.

According to various aspects, the present disclosure generally relates to an integrated circuit having a stacked embedded passive substrate (EPS) structure formed therein. In particular, a substrate may have a cavity formed therein and the stacked EPS structure may include multiple passive components formed in the cavity to provide separate electrical paths for decoupling of the integrated circuit. Furthermore, the multiple passive components may each have two respective terminals such that the multiple passive components may support different voltage domains. Among other things, compared to conventional die-side and/or land-side passive components, the stacked EPS structure may advantageously reduce a z-axis height of the integrated circuit, reduce manufacturing costs, improve performance due to shorter electrical paths, and improve design routing through x-axis and y-axis space savings.

According to various aspects, a semiconductor package may comprise a substrate having a cavity formed therein, a semiconductor die attached to the substrate, and a stacked EPS structure formed in the substrate cavity, wherein the stacked EPS structure may comprise a first passive component connected to the semiconductor die and to a printed circuit board (PCB) in a first electrical path (e.g., through a ball in a ball grid array (BGA)), and wherein the stacked EPS structure further comprises a second passive component connected to the semiconductor die in a second electrical path.

According to various aspects, a method for manufacturing a semiconductor package may comprise forming a cavity in a substrate, forming a stacked EPS structure in the substrate cavity, wherein the stacked EPS structure comprises a first passive component and a second passive component and attaching a semiconductor die to the substrate, wherein the first passive component is connected to the semiconductor die and to a printed circuit board (PCB) in a first electrical path (e.g., through a ball in a ball grid array (BGA)), and wherein the second passive component is connected to the semiconductor die in a second electrical path.

According to various aspects, a method for embedding multiple passive components in a substrate may comprise forming a cavity in a core layer of the substrate, stacking a first passive component and a second passive component in the cavity, and patterning one or more outer layers of the substrate to surround the first passive component and the second passive component stacked within the cavity.

According to various aspects, an apparatus may comprise a substrate having a core layer and one or more outer layers surrounding the core layer, a first passive component embedded in the core layer, wherein the first passive component may comprise a first pair of electrodes routed to a first voltage domain, and a second passive component embedded in the core layer, wherein the second passive component may comprise a second pair of electrodes routed to a second voltage domain, and wherein the first passive component and the second passive component may be vertically stacked within a single cavity formed in the core layer of the substrate.

Other objects and advantages associated with the aspects and embodiments disclosed herein will be apparent to those skilled in the art based on the accompanying drawings and detailed description.

### BRIEF DESCRIPTION OF THE DRAWINGS

A more complete appreciation of the various aspects and embodiments described herein and many attendant advantages thereof will be readily obtained as the same becomes better understood by reference to the following detailed description when considered in connection with the accompanying drawings which are presented solely for illustration and not limitation, and in which:

FIG. 1 illustrates an exemplary semiconductor package depicting various locations where a passive component may be placed, according to various aspects.

FIG. 2 illustrates a comparison between a semiconductor package with one or more die-side and/or land-side capacitors relative to a semiconductor package including a stacked embedded passive substrate (EPS) structure, according to various aspects.

FIGS. 3A-FIG. 3F illustrate various exemplary configurations for the stacked EPS structure described herein, according to various aspects.

FIGS. 4A-FIG. 4H illustrate exemplary starting, intermediate, and/or final structures during a process for fabricating a semiconductor package that includes a stacked EPS structure, according to various aspects.

FIG. 5 illustrates an exemplary method for fabricating a semiconductor package that includes a stacked EPS structure, according to various aspects.

FIG. 6 illustrates an exemplary communication system including one or more electronic devices that may implement the stacked EPS structure described herein, according to various aspects.

### DETAILED DESCRIPTION

According to various aspects, passive components such as capacitors are often used in electronic packaging to reduce noise and impedance and to maintain a near-constant voltage under various operating frequencies. In general, there are only a few locations in a semiconductor package where such passive components can be placed.

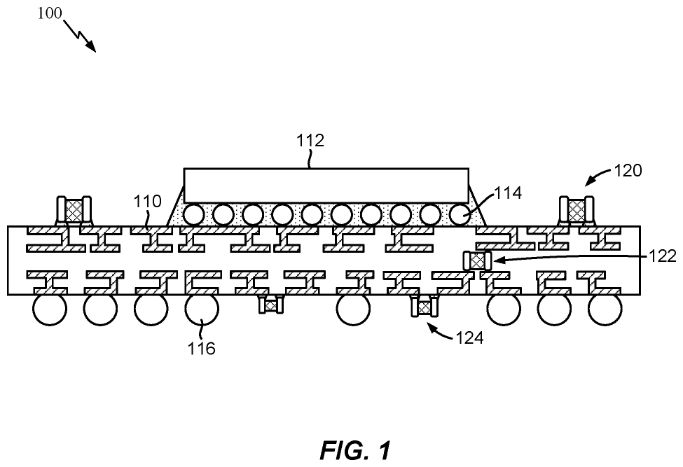

For example, FIG. 1 illustrates an exemplary semiconductor package 100 depicting various locations where a passive component may be placed. In FIG. 1, the semiconductor package 100 includes a substrate 110 and a semiconductor die 112. The semiconductor die 112 is attached to a front side of the substrate 110 by ball grid array (BGA) packaging 114. However, those skilled in the art will appreciate that other suitable packaging methods may also be used to attach the semiconductor die 112 to the substrate 110, such as a pin grid array (PGA) or land grid array (LGA). The substrate 110 also includes a ball grid array (BGA) packaging 116 to facilitate further processing. The substrate 110 may also include various interconnects to support various functions of the semiconductor package 100.

One possible configuration to decouple the integrated circuit to reduce impedance, maintain a constant voltage, or otherwise improve performance is to place a decoupling capacitor on top of the substrate 110, depicted in FIG. 1 as a die-side capacitor (DSC) 120. As the name implies, the die-side capacitor 120 is attached to the substrate 110 on the die side, adjacent to the semiconductor die 112. The die-side capacitor 120 is typically relatively cheap to manufacture, as the die-side capacitor 120 is conventionally made from a fairly thick (and thus inexpensive) MLCC. However, the die-side capacitor 120 has various limitations and drawbacks, including that the die-side configuration occupies area that could otherwise be used for active circuitry. Furthermore, because a thick MLCC is typically used to form the die-side capacitor 120, the die-side placement increases the height of the semiconductor package 100.

A second possible decoupling configuration is to place the decoupling capacitor on the land side of the substrate 110 under the die shadow, depicted in FIG. 1 as a land-side capacitor (LSC) 124. The land side of the substrate 110 is the side populated by the BGA packaging 116 for coupling to external circuits (not explicitly shown in FIG. 1). Although placing the land-side capacitor 124 on the land side of the substrate 110 does not consume active areas, the land-side capacitor 124 must be thin enough to fit within the constrained height of the connectors associated with the BGA packaging 116. As such, the thin MLCC conventionally used as the land-side capacitor 124 tends to be more expensive than the die-side capacitor 120 in addition to having a design routing limitation, in that the land-side capacitor 124 has to be placed in a depopulated area within the BGA packaging 116.

The third possible location for placing the decoupling capacitor is within the substrate 110, depicted in FIG. 1 as an embedded passive substrate (EPS) structure 122. However, embedding the EPS structure 122 in the substrate 110 as conventionally implemented in FIG. 1 is a costly endeavor, as additional processes and materials are used to form and integrate the EPS structure 122 into the substrate 110. Furthermore, in conventional implementations as shown in FIG. 1, the cavity formed in the substrate 110 can only accommodate one EPS structure 122. However, there are various cases in which an integrated circuit may benefit from multiple passives that may operate in different voltage domains (e.g., one passive for signal and another for power). Compared to the die-side capacitor 120 and the land-side capacitor 124, the EPS structure 122 advantageously offers a reduced package footprint, shorter signal path(s), and improved power delivery performance. As such, methods to embed multiple passive components in a given substrate cavity are desired and described herein.

Various aspects and embodiments are disclosed in the following description and related drawings to show specific examples relating to exemplary aspects and embodiments. Alternate aspects and embodiments will be apparent to those skilled in the pertinent art upon reading this disclosure, and may be constructed and practiced without departing from the scope or spirit of the disclosure. Additionally, well-known elements will not be described in detail or may be omitted so as to not obscure the relevant details of the aspects and embodiments disclosed herein.

The word “exemplary” is used herein to mean “serving as an example, instance, or illustration.” Any aspect or embodiment described herein as “exemplary” is not necessarily to be construed as preferred or advantageous over other aspects or embodiments. Likewise, the terms “aspects” and “embodiments” do not require that all aspects or embodiments include the discussed feature, advantage, or mode of operation.

The terminology used herein describes particular aspects only and should not be construed to limit any aspects disclosed herein. As used herein, the singular forms “a,” “an,” and “the” are intended to include the plural forms as well, unless the context clearly indicates otherwise. Those skilled in the art will further understand that the terms “comprises,” “comprising,” “includes,” and/or “including,” as used herein, specify the presence of stated features, integers, steps, operations, elements, and/or components, but do not preclude the presence or addition of one or more other features, integers, steps, operations, elements, components, and/or groups thereof.

The terms “connected,” “coupled,” and any variant thereof as used herein are intended to refer to any suitable connection or coupling between elements, either direct or indirect, and can encompass a presence of one or more intermediate elements between two elements that are “connected” or “coupled” together via the intermediate element(s). Coupling and connection between the elements can be physical, logical, or any combination thereof. Elements can be “connected” or “coupled” together, for example, using one or more wires, cables, printed electrical connections, electromagnetic energy, and the like. The electromagnetic energy can have a wavelength at a radio frequency, a microwave frequency, a visible optical frequency, an invisible optical frequency, and the like, as practicable. These are several non-limiting and non-exhaustive examples.

In the following description, spatial terms (e.g., “top,” “middle,” “bottom,” “left,” “center,” “right,” “up,” “down,” “vertical,” “horizontal,” “on,” “above,” “under,” etc.) as used herein are for illustrative purposes only, and are not limiting descriptors. Practical implementations of the structures described herein can be spatially arranged in any practicable orientation providing the functions described hereby. In addition, in using the term “adjacent” herein to describe a spatial relationship between integrated circuit elements, the adjacent integrated circuit elements need not be in direct physical contact, and other integrated circuit elements can be located between the adjacent integrated circuit elements.

In various embodiments, the devices, apparatuses, and/or structures described in further detail below can be part of, connected to, and/or coupled to a suitable electronic device such as, but not limited to, a mobile device, a base station, a navigation device (e.g., a global positioning system receiver), a wireless device, a camera, an audio player, a camcorder, a game console, a server, an automotive device, or the like.

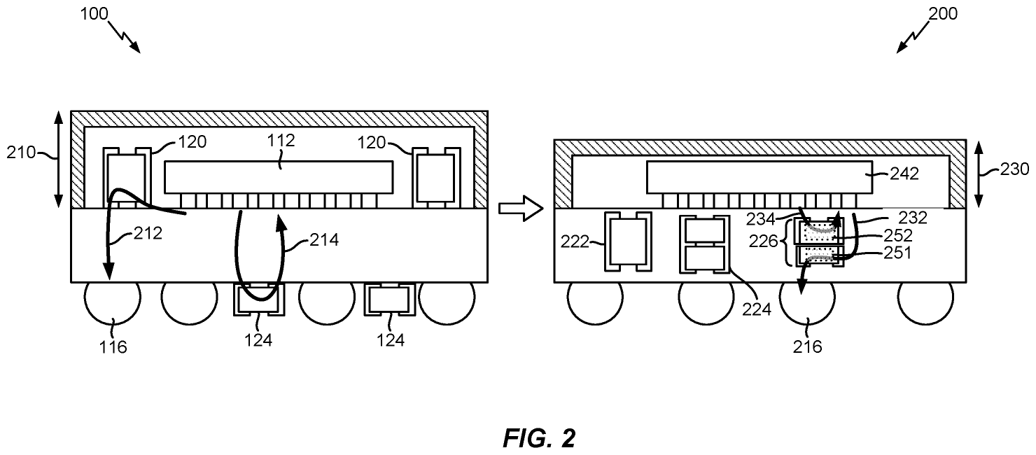

According to various aspects, FIG. 2 illustrates a comparison between the semiconductor package 100 shown in FIG. 1, which includes one or more die-side capacitors 120 and/or land-side capacitors 124, relative to a semiconductor package 200 that includes one or more embedded passive substrate (EPS) structures.

For example, as illustrated in FIG. 2, the semiconductor package 100 includes one or more die-side capacitors 120, which have a thickness/height that can increase the total height of the semiconductor package 100. For example, because the die-side capacitors 120 have a greater height than the combined height of the semiconductor die 112 and the BGA packaging 114, integrated circuit packaging 210 (e.g., a protective casing made from metal, plastic, glass, ceramic, or another suitable material) has to be taller than the die-side capacitors 120, which adds to the total height of the semiconductor package 100. Furthermore, placing the die-side capacitor 120 on the same side of the substrate 110 as the semiconductor die 112 results in a comparatively long signal path 212, which has to flow outward from the BGA packaging 114 on the die side before passing through the die-side capacitor 120 and then through the substrate 110 to the BGA packaging 116 on the land side. Similar issues may arise with respect to the one or more land-side capacitors 124, as a core power path 214 has to travel the entire height of the substrate 110 to the land-side capacitor 124 and then again travel the entire height of the substrate 110 to deliver power to the semiconductor die 112 on the die side. In either case, the length of the signal path 212 and the core power path 214 can lead to undesirable response times and reduced performance due to inductance in the wire or trace. In addition, the land-side capacitor 124 has a design routing limitation, in that the land-side capacitor 124 has to be placed in depopulated areas of the BGA packaging 116 and also has to be thinner than the ball height of the BGA packaging 116. Still another drawback of the semiconductor package 100 is that having passive components on both the die-side and the land-side requires multiple MLCC attachments and reflow operations, which may introduce additional manufacturing costs.

Accordingly, in FIG. 2, the semiconductor package 200 that has one or more embedded passive substrate (EPS) structures may offer various advantages over the semiconductor package 100 in which passive components 120, 124 are placed on the die-side and the land-side. For example, the semiconductor package 200 includes a first embedded passive substrate (EPS) structure 222 having a similar structural configuration as the die-side capacitors 120 (e.g., similar materials/thickness), a first stacked EPS structure 224 that includes two passive components that each have a similar structural configuration as the land-side capacitors 124, and a second stacked EPS structure 226 that includes a first passive component 251 arranged to provide a signal path 232 from a semiconductor die 242 on the die-side to BGA packaging 216 on the land-side and a second passive component 252 arranged to provide a core power path 234 for the semiconductor die 242. In the example shown in FIG. 2, the first passive component 251 providing the signal path 232 may therefore be connected to both the semiconductor die 242 and a printed circuit board (PCB) (not explicitly shown) through a ball associated with the BGA packaging 216, while the second passive component 252 providing the core power path 234 is connected to the semiconductor die 242.

Accordingly, as shown in FIG. 2, one advantage of the semiconductor package 200 relative to the semiconductor package 100 is that integrated circuit packaging 230 used to protect and stabilize the semiconductor package 200 may have a reduced height relative to the integrated circuit packaging 210 used in the conventional semiconductor package 100, as there are no capacitors or other components on the die-side that have a z-axis height greater than the combined z-axis height of the semiconductor die 242 and any bumping or other packaging used to connect the semiconductor die 242 to the underlying substrate. Furthermore, the design of the semiconductor package 200 may offer a cost benefit, in that the various EPS structures 222, 224, 226 can be manufactured in fewer and more efficient steps, as will be described in further detail below. Further still, the semiconductor package 200 may offer better performance due to a shorter signal path 232 and a shorter core power path 234. For example, in the stacked EPS structure 226, stacking the first passive component 251 and second passive component 252 substantially shortens the core power path 234 through the upper passive component, which may reduce inductance in the wire or trace and thereby reduce the response time to increase power, among other performance benefits as would be apparent to those skilled in the art. Furthermore, because the first passive component 251 located in the signal path 232 is under the die shadow, the signal path 232 is substantially shortened, which also improves performance for similar reasons.

According to various aspects, yet another advantage is improved design routing based on x-axis and y-axis space savings, in that no space on the die-side or the land-side has to be reserved to accommodate the die-side capacitor 120 or land-side capacitor 124. As such, additional active components (not explicitly shown) could potentially be added on the die-side, the BGA packaging 216 on the land-side can be evenly spaced rather than spaced in such a way as to leave a depopulated area for placing passive components, and so on. Furthermore, whereas a single EPS structure (e.g., EPS structure 122 and/or 222) only has two terminals, one for a negative supply voltage (V_{SS}) and one for a positive supply voltage (V_{DD}), the passive components making up the stacked EPS structures 224 and 226 may be relatively thin passive components that can be arranged back-to-back. This may result in a structure similar to a conventional MLCC, except that the multiple stacked passive components may have four terminals, which can therefore be used to support two V_{DDA} domains and two V_{SSA} domains.

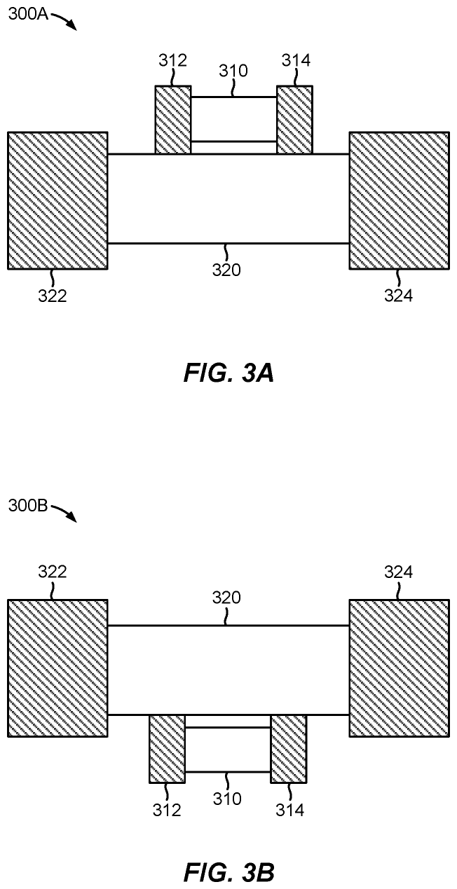

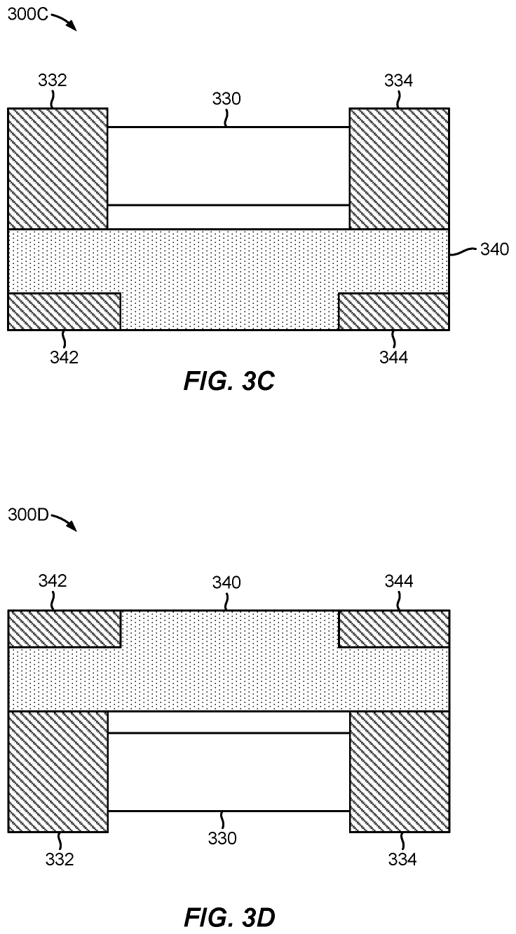

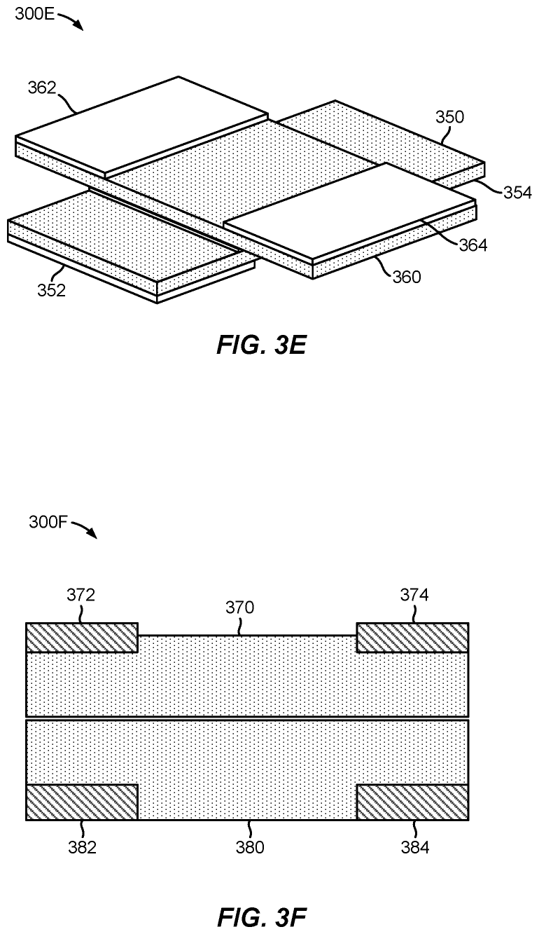

For example, FIGS. 3A-3F illustrate various exemplary four-terminal configurations that may be used in the stacked EPS structure 224 and/or the stacked EPS structure 226 that includes the first passive component arranged to provide the signal path 232 and the second passive component arranged to provide the core power path 234. In general, the various configurations shown in FIGS. 3A-3F may each be embedded inside an appropriate multi-layer substrate (e.g., a substrate comprising four or more layers) in an arrangement whereby the four terminals are not touching or otherwise electrically connected to one another. Consequently, the configurations shown in FIGS. 3A-3F may each be used to support current paths in multiple voltage domains.

More particularly, in a first example, FIG. 3A illustrates a cross-sectional view of a stacked EPS structure 300A that includes a first MLCC 310 stacked above a second MLCC 320, wherein the first MLCC 310 has a smaller footprint than the second MLCC 320. As such, the first MLCC 310 has two electrodes 312, 314 that could be routed to V_{DD} and V_{SS} in a first voltage domain through one or more vias formed in one or more outer substrate layers, while the second MLCC 320 has two electrodes 322, 324 that are not touching either of electrodes 312, 314 such that electrodes 322, 324 may be routed to V_{DD} and V_{SS} in a second voltage domain. Furthermore, FIG. 3B illustrates a stacked EPS structure 300B substantially similar to the stacked EPS structure 300A, except that the orientation of the first MLCC 310 and the second MLCC 320 has been reversed.

In another example, FIG. 3C illustrates a cross-sectional view of a stacked EPS structure 300C that includes an MLCC 330 stacked on a silicon capacitor 340, wherein an adhesive material (not explicitly shown) may be formed between the MLCC 330 and the silicon capacitor 340. For example, in various embodiments, the adhesive material may be an adhesive epoxy, cyanoacrylate, silicone, polyurethane, thermoplastic, elastomeric adhesive, thermoset adhesive, UV-curable adhesive, hot curing adhesive, hot-melt adhesive, phenolic, acrylic, acrylate, polyamide, contact adhesive, pressure sensitive adhesive (PSA), or the like. As shown in FIG. 3C, the MLCC 330 has two electrodes 332, 334 that may be attached to the adhesive material without touching the two electrodes 342, 344 coupled to the silicon capacitor 340. Consequently, the two electrodes 332, 334 associated with the MLCC 330 may be routed to V_{DD} and V_{SS} in a first voltage domain and the two electrodes 342, 344 associated with the silicon capacitor 340 may be routed to V_{DD} and V_{SS} in a second voltage domain. Furthermore, FIG. 3D illustrates a stacked EPS structure 300D substantially similar to the stacked EPS structure 300C, except that the orientation of the MLCC 330 and the silicon capacitor 340 has been reversed.

In still another example, FIG. 3E illustrates a top-view of a stacked EPS structure 300E that includes a first MLCC 350 and a second MLCC 360 arranged at a ninety (90) degree rotation relative to the first MLCC 350. As such, the 90 degree rotation may ensure that electrodes 352, 354, 362, 364 are not touching one another such that the first MLCC 350 may support a first voltage domain and the second MLCC 360 may support a second voltage domain.

In still another example, FIG. 3F illustrates a cross-sectional view of a stacked EPS structure 300F that includes two silicon capacitors 370, 380 with an adhesive material (not explicitly shown) formed between the two silicon capacitors 370, 380. As such, the two silicon capacitors 370, 380 may be stacked back-to-back and the adhesive material and shape of the silicon capacitors 370, 380 may ensure that electrodes 372, 374, 382, 384 are not touching one another such that the two silicon capacitors 370, 380 can be appropriately routed to different voltage domains.

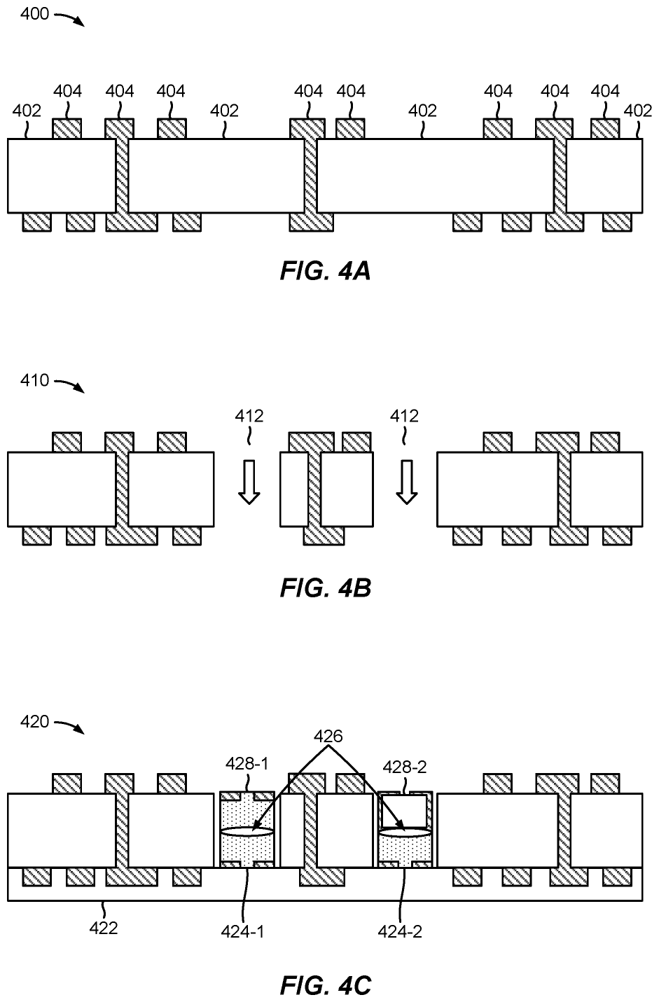

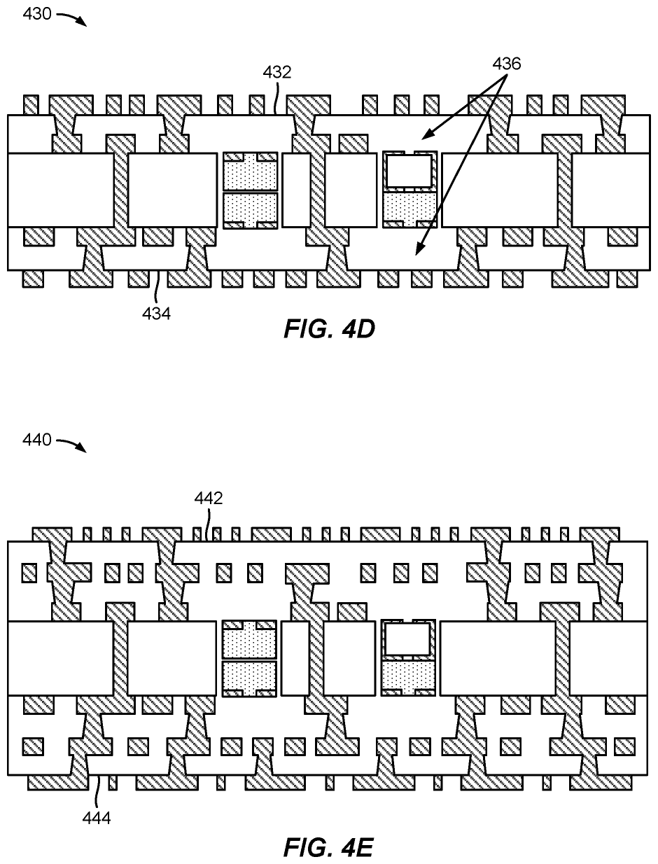

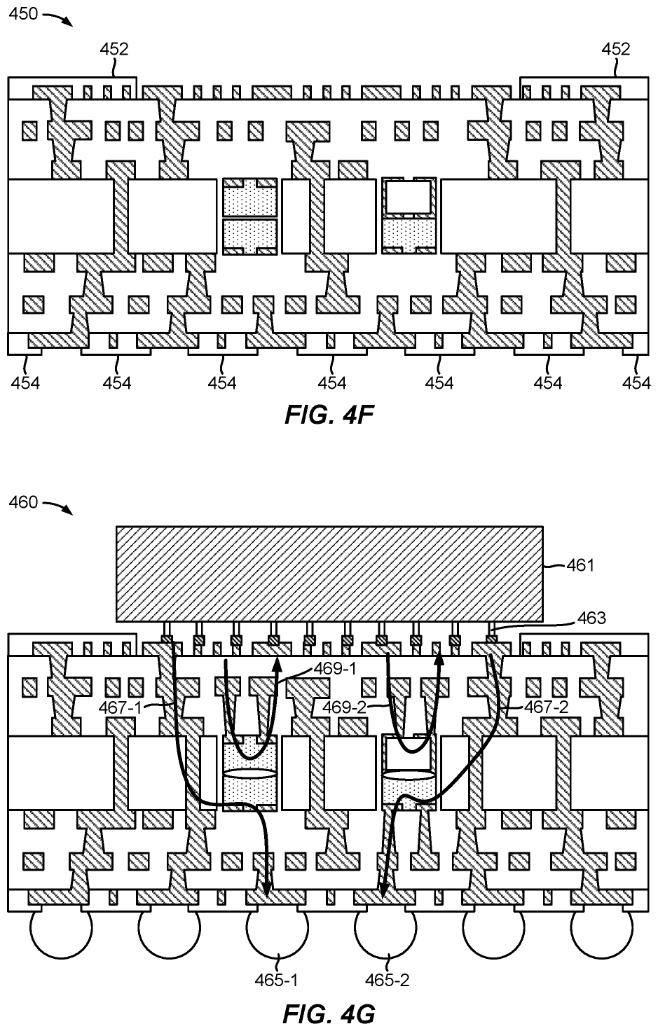

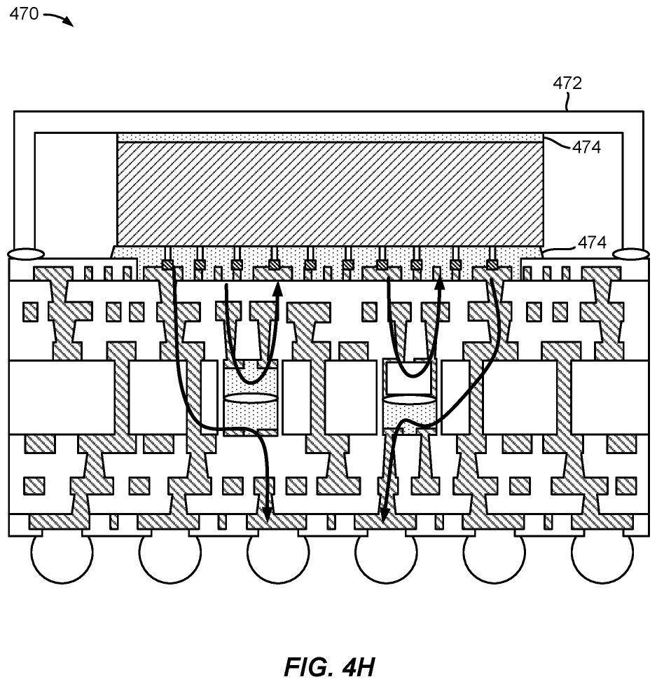

According to various aspects, with reference to FIGS. 4A-4H, an exemplary process for fabricating a semiconductor package that includes one or more stacked EPS structures having any one or more of the configurations shown in FIGS. 3A-3F will now be described with reference to certain starting, intermediate, and/or final structures.

More particularly, FIG. 4A illustrates an exemplary structure 400 that may be formed from patterning a core layer 402 of a substrate and patterning various metal layers 404 that serve as redistribution layers to route conductor patterns and reroute interlayer via connections to other areas of the substrate. One or more cavities 412 may then be formed in the core layer 402, resulting in the structure 410 shown in FIG. 4B. For example, when a thickness of the core layer 402 is less than approximately 250 μm, the one or more cavities 412 may be formed using copper etching or laser drilling. In one alternative, when the thickness of the core layer 402 is greater than approximately 250 μm, the one or more cavities 412 may be formed using mechanical drilling. However, those skilled in the art will appreciate that other techniques may be used to form the one or more cavities 412, possibly based on the thickness of the core layer 402.

In various embodiments, FIG. 4C illustrates a structure 420 that may result from applying one or more chip attachment processes to the structure 410 shown in FIG. 4B. For example, in various embodiments, a polyimide (PI) tape 422 may first be attached to the core layer 402 and the metal layers 404 on one side. One or more first passive components 424-1, 424-2 may then be attached to the PI tape 422 before an adhesive material 426 (e.g., approximately 10 μm thick) is formed on the first passive components 424-1, 424-2. For example, as noted above, the adhesive material 426 may be an adhesive epoxy, cyanoacrylate, silicone, polyurethane, thermoplastic, elastomeric adhesive, thermoset adhesive, UV-curable adhesive, hot curing adhesive, hot-melt adhesive, phenolic, acrylic, acrylate, polyamide, contact adhesive, pressure sensitive adhesive (PSA), etc. One or more second passive components 428-1, 428-2 can then be attached to the adhesive material 426, resulting in the structure 420.

In various embodiments, FIG. 4D illustrates a structure 430 that may result from applying one or more patterning processes to the structure 420 shown in FIG. 4C. For example, FIG. 4D illustrates one or more outer substrate layers 432, 434 patterned around the core layer 402 as shown in FIGS. 4A-4C as well as further patterning of the metal layers 404. Furthermore, as depicted at 436, the outer substrate layers 432, 434 may be patterned in such a way as to allow for subsequent formation of one or more vias that may be needed to route connections to the stacked passive components 424, 428. In various embodiments, FIG. 4E illustrates a structure 440 that may result from applying further patterning to the structure 430 shown in FIG. 4D, wherein the structure 440 shown in FIG. 4E includes additional substrate layers 442, 444 patterned around the substrate layers 432, 434 shown in FIG. 4D.

In various embodiments, FIG. 4F illustrates a structure 450 that may result from applying one or more further processes to the structure 440 shown in FIG. 4E. For example, in various embodiments, a plating and surface finish (PSR) process may be used to apply a coating that may provide protection and durability to the die-side and land-side surfaces. Furthermore, the PSR process may be used to form one or more contacts 452 on the die-side for subsequent attachment to integrated circuit packaging and one or more contacts 454 may also be formed on the land-side for subsequent attachment to one or more solder balls 465-1, 465-2 forming land-side ball grid array (BGA) packaging, as depicted in FIG. 4G, which illustrates a structure 460 that may result from applying one or more further processes to the structure 450 shown in FIG. 4F. For example, in FIG. 4G, the solder balls 465-1, 465-2 making up the land-side BGA packaging have been formed, and a semiconductor die 461 has been attached through die-side BGA packaging 463. FIG. 4G further illustrates various electrical paths that have been connected or otherwise routed to the stacked passive components 424, 428. For example, FIG. 4G illustrates a first signal path 467-1 routed to first passive component 424-1 and a first core power path 469-1 routed to second passive component 428-1 as well as a second signal path 467-2 routed to first passive component 424-2 and a second core power path 469-2 routed to second passive component 428-2. In various embodiments, FIG. 4H illustrates a final structure 470 that may result from applying one or more further processes to the structure 460 shown in FIG. 4G. More particularly, in FIG. 4H, integrated circuit packaging 472 has been formed to protect underlying components and to stabilize the entire structure 470, and an underfill material 474 has been formed in areas between the semiconductor die 461 and the die-side BGA packaging 463 according to techniques that will be apparent to those skilled in the art.

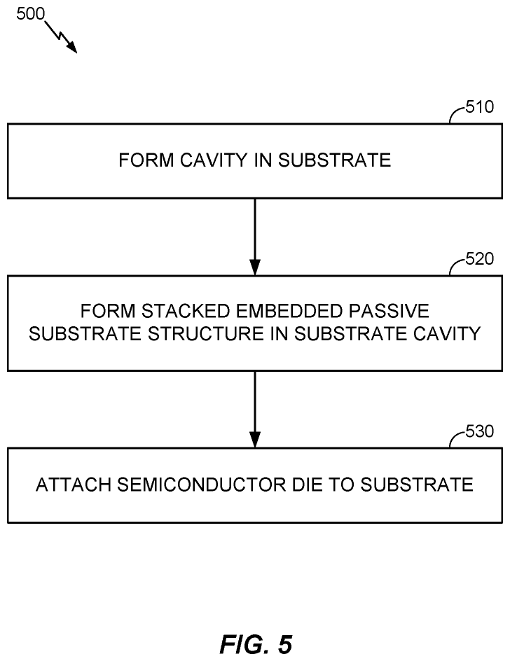

FIG. 5 illustrates an exemplary method 500 for fabricating a semiconductor package that includes a stacked EPS structure having the characteristics described in further detail above. More particularly, at block 510, a cavity may be formed in a substrate (e.g., a core layer of the substrate). For example, in various embodiments, the cavity may be formed using one or more of copper etching or laser drilling when the core layer of the substrate has a thickness of less than approximately 250 μm. Alternatively, the cavity may be formed using mechanical drilling when the core layer of the substrate has a thickness of greater than approximately 250 μm. In various embodiments, at block 520, the stacked EPS structure may then be formed in the substrate cavity. For example, in various embodiments, the stacked EPS structure may have any one or more of the various configurations shown in FIGS. 3A-3F. In various embodiments, the stacked EPS structure may be formed as described in further detail above with respect to FIG. 4C. For example, block 520 may comprise attaching an adhesive (e.g., polyimide tape) on one side of the cavity, attaching a first passive component to the adhesive and stacking the second passive component above the first passive component such that electrodes coupled to the first and second passive components do not touch one another, as shown in FIGS. 3A-3F. Furthermore, depending on the particular configuration of the stacked EPS structure, an adhesive material may be formed between the first passive component and the second passive component (e.g., where one or both passive components is a silicon capacitor). In various embodiments, at block 530, a semiconductor die may then be attached to the substrate. For example, as shown in FIGS. 4D-4G, one or more outer layers of the substrate may be patterned to surround the stacked EPS structure prior to applying a plating and surface finish process to the outermost layers of the substrate (e.g., a die-side and land-side of the substrate). The semiconductor die may then be attached to the substrate using any suitable means, such as a ball grid array (BGA) attachment. Furthermore, one or more vias may be used to form connections to the first and second passive components embedded in the substrate, which may allow for separate electrical paths connecting the first and second passive components to the semiconductor die (e.g., to provide a signal path and a core power path, to support different voltage domains, etc.).

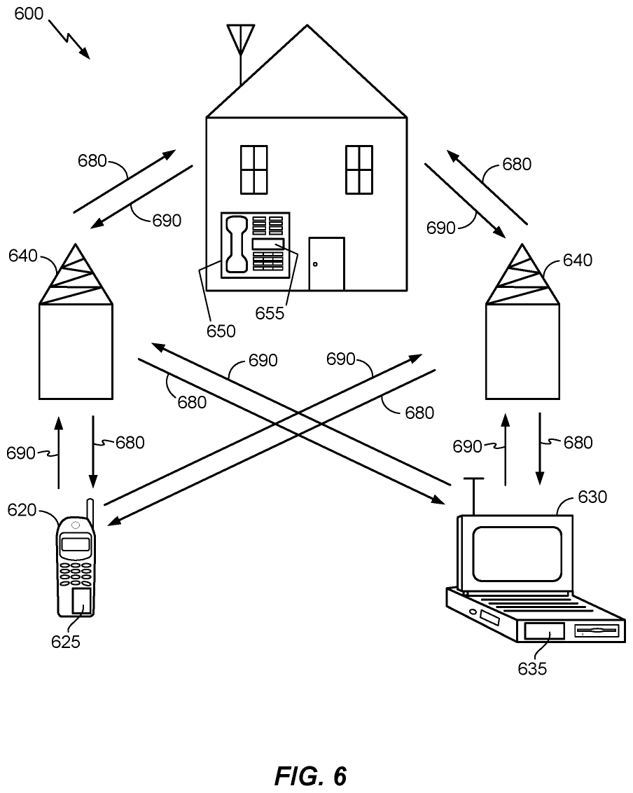

According to various aspects, FIG. 6 illustrates an exemplary communication system 600 including one or more electronic devices that may implement the stacked EPS structure described in further detail above. For example, for purposes of illustration, FIG. 6 shows three remote units 620, 630, and 650 and two base stations 640. However, those skilled in the art will recognize that the wireless communication system 600 may have more or fewer remote units and/or base stations in different possible deployments. In the illustrated example, the remote units 620, 630, and 650 may each include one or more integrated circuit or other semiconductor devices 625, 635, 655, respectively, having one or more stacked embedded passive substrate (EPS) structures formed therein in accordance with one or more of the disclosed exemplary aspects as claimed or as described herein. FIG. 6 shows forward link signals 680 from the base stations 640 to the remote units 620, 630, 650 and reverse link signals 690 from the remote units 620, 630, 650 to the base stations 640.

According to various aspects, in FIG. 6, the remote unit 620 is shown as a mobile telephone, the remote unit 630 is shown as a portable computer, and the remote unit 650 is shown as a fixed location remote unit in a wireless local loop system. These are only examples, both in terms of quantity and type. For example, the remote units 620, 630, 650 may be one of, or any combination of a mobile phone, hand-held personal communication system (PCS) unit, portable data unit such as a personal data assistant (PDA), navigation device (e.g., a GPS enabled device), set top box, music player, video player, entertainment unit, fixed location data unit (e.g., meter reading equipment), server, automotive device, or any other electronic device that can receive and/or transmit wireless signals or any combination thereof. Although FIG. 6 illustrates remote units 620, 630, 650 according to aspects of the disclosure, the disclosure is not limited to these exemplary illustrated units. Aspects of the disclosure may be suitably employed in any electronic device that can benefit from implementing a stacked EPS structure (e.g., to support multiple power domains, a smaller form factor due to an overall z-axis height reduction, better performance through shorter power and/or signal paths, improve design routing through x-axis and y-axis space savings, etc.).

For example, the stacked EPS structure disclosed herein may be incorporated into a device such as a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, or a device in an automotive vehicle. Further, those skilled in the art will appreciate that aspects disclosed herein may be used a wide variety of devices and are not limited to the specific examples provided herein.

The devices, structures, and functionalities (e.g., fabrication methods) may be designed and configured into computer files (e.g., RTL, GDSII, GERBER, etc.) stored on computer-readable media. Some or all of such files may be provided to fabrication handlers who fabricate devices based on such files. Resulting products may include semiconductor wafers that are then cut into semiconductor die and packaged into a semiconductor chip. The chips may then be employed in devices described above.

In order to fully illustrate aspects of the stacked EPS structure design disclosed herein, certain fabrication methods are described above. However, other suitable fabrication methods are possible, whereby the fabrication method(s) disclosed herein are presented only to aid understanding of and not to limit the aspects disclosed herein.

Those skilled in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those skilled in the art will appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted to depart from the scope of the various aspects described herein.

The various illustrative logical blocks, modules, and circuits described in connection with the aspects disclosed herein may be implemented or performed with a general purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or other such configurations).

The methods, sequences, and/or algorithms described in connection with the aspects disclosed herein may be embodied directly in hardware, in a software module executed by a processor, or in a combination of the two. A software module may reside in Random Access Memory (RAM), flash memory, Read-Only Memory (ROM), Erasable Programmable ROM (EPROM), Electrically Erasable Programmable ROM (EEPROM), registers, hard disk, a removable disk, a CD-ROM, or any other form of non-transitory computer-readable medium known in the art. An exemplary non-transitory computer-readable medium may be coupled to the processor such that the processor can read information from, and write information to, the non-transitory computer-readable medium. In the alternative, the non-transitory computer-readable medium may be integral to the processor. The processor and the non-transitory computer-readable medium may reside in an ASIC. The ASIC may reside in a user device or a base station. In the alternative, the processor and the non-transitory computer-readable medium may be discrete components in a user device or base station.

In one or more exemplary aspects, the functions described herein may be implemented in hardware, software, firmware, or any combination thereof. If implemented in software, the functions may be stored on or transmitted over as one or more instructions or code on a non-transitory computer-readable medium. Computer-readable media may include storage media and/or communication media including any non-transitory medium that may facilitate transferring a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, DSL, or wireless technologies such as infrared, radio, and microwave, then the coaxial cable, fiber optic cable, twisted pair, DSL, or wireless technologies such as infrared, radio, and microwave are included in the definition of a medium. The term disk and disc, which may be used interchangeably herein, includes a Compact Disk (CD), laser disc, optical disk, Digital Video Disk (DVD), floppy disk, and Blu-ray discs, which usually reproduce data magnetically and/or optically with lasers. Combinations of the above should also be included within the scope of computer-readable media.

While the foregoing disclosure shows illustrative aspects, those skilled in the art will appreciate that various changes and modifications could be made herein without departing from the scope of the disclosure as defined by the appended claims. Furthermore, in accordance with the various illustrative aspects described herein, those skilled in the art will appreciate that the functions, steps, and/or actions in any methods described above and/or recited in any method claims appended hereto need not be performed in any particular order. Further still, to the extent that any elements are described above or recited in the appended claims in a singular form, those skilled in the art will appreciate that singular form(s) contemplate the plural as well unless limitation to the singular form(s) is explicitly stated.

What is claimed is:

1. A semiconductor package, comprising:
a substrate having a cavity formed therein;
a semiconductor die attached to the substrate; and
a stacked embedded passive substrate (EPS) structure formed in the substrate cavity, wherein the stacked EPS structure comprises:
a first passive component connected to the semiconductor die and to a printed circuit board (PCB) in a first electrical path, and
a second passive component connected to the semiconductor die in a second electrical path.

2. The semiconductor package recited in claim 1, wherein the stacked EPS structure further comprises:
a first pair of electrodes coupled to the first passive component; and
a second pair of electrodes coupled to the second passive component, wherein the first pair of electrodes do not contact the second pair of electrodes.

3. The semiconductor package recited in claim 2, wherein the first and second passive components are multi-layer ceramic capacitors.

4. The semiconductor package recited in claim 3, wherein the multi-layer ceramic capacitors have different sizes.

5. The semiconductor package recited in claim 3, wherein the multi-layer ceramic capacitors are arranged at a ninety degree rotation relative to one another.

6. The semiconductor package recited in claim 2, wherein the first and second passive components are silicon capacitors stacked back-to-back.

7. The semiconductor package recited in claim 2, wherein the first passive component is a multi-layer ceramic capacitor and the second passive component is a silicon capacitor.

8. The semiconductor package recited in claim 1, wherein one or more of the first electrical path or the second electrical path is a signal path.

9. The semiconductor package recited in claim 1, wherein one or more of the first electrical path or the second electrical path is a core power path.

10. The semiconductor package recited in claim 1, wherein the stacked EPS structure further comprises an adhesive material formed between the first passive component and the second passive component.

11. The semiconductor package recited in claim 1, wherein the first electrical path and the second electrical path are routed to different voltage domains.

12. The semiconductor package recited in claim 1, wherein the cavity is formed in a core layer of the substrate and wherein the substrate further includes one or more outer layers surrounding the stacked EPS structure.

13. A method for manufacturing a semiconductor package, comprising:
forming a cavity in a substrate;
forming a stacked embedded passive substrate (EPS) structure in the substrate cavity, wherein the stacked EPS structure comprises a first passive component and a second passive component; and
attaching a semiconductor die to the substrate, wherein the first passive component is connected to the semiconductor die and to a printed circuit board (PCB) in a first electrical path, and wherein the second passive component is connected to the semiconductor die in a second electrical path.

14. The method recited in claim 13, wherein forming the stacked EPS structure further comprises:
forming a first pair of electrodes coupled to the first passive component; and
forming a second pair of electrodes coupled to the second passive component, wherein the first pair of electrodes do not contact the second pair of electrodes.

15. The method recited in claim 14, wherein the first and second passive components are multi-layer ceramic capacitors.

16. The method recited in claim 15, wherein the multi-layer ceramic capacitors have different sizes.

17. The method recited in claim 15, wherein forming the stacked EPS structure further comprises arranging the multi-layer ceramic capacitors at a ninety degree rotation relative to one another.

18. The method recited in claim 14, wherein the first and second passive components are silicon capacitors stacked back-to-back.

19. The method recited in claim 14, wherein the first passive component is a multi-layer ceramic capacitor and the second passive component is a silicon capacitor.

20. The method recited in claim 13, wherein one or more of the first electrical path or the second electrical path is a signal path.

21. The method recited in claim 13, wherein one or more of the first electrical path or the second electrical path is a core power path.

22. The method recited in claim 13, wherein forming the stacked EPS structure further comprises forming an adhesive material between the first passive component and the second passive component.

23. The method recited in claim 13, wherein the first electrical path and the second electrical path are routed to different voltage domains.

24. The method recited in claim 13, wherein the cavity is formed in a core layer of the substrate and wherein the method further comprises patterning one or more outer layers of the substrate to surround the stacked EPS structure.

25. A method for embedding multiple passive components in a substrate, comprising:
forming a cavity in a core layer of the substrate;
stacking a first passive component and a second passive component in the cavity; and
patterning one or more outer layers of the substrate to surround the first passive component and the second passive component stacked within the cavity.

26. The method recited in claim 25, wherein the core layer of the substrate has a thickness of less than approximately 250 μm and the cavity is formed using one or more of copper etching or laser drilling.

27. The method recited in claim 25, wherein the core layer of the substrate has a thickness of greater than approximately 250 m and the cavity is formed using mechanical drilling.

28. The method recited in claim 25, wherein stacking the first passive component and the second passive component in the cavity comprises:
attaching an adhesive on one side of the cavity;
attaching the first passive component to the adhesive; and
stacking the second passive component above the first passive component such that electrodes coupled to the first and second passive components do not touch one another.

29. The method recited in claim 25, wherein stacking the first passive component and the second passive component in the cavity comprises forming an adhesive material between the first passive component and the second passive component.

30. An apparatus, comprising:
a substrate having a core layer and one or more outer layers surrounding the core layer;
a first passive component embedded in the core layer, wherein the first passive component comprises a first pair of electrodes routed to a first voltage domain; and
a second passive component embedded in the core layer, wherein the second passive component comprises a second pair of electrodes routed to a second voltage domain, and wherein the first passive component and the second passive component are vertically stacked within a single cavity formed in the core layer of the substrate.
